(19) United States
(12) Patent Application Publication
(10) Pub. No.: US 2025/0311464 A1
(43) Pub. Date: Oct. 2, 2025

(54) CMOS IMAGE SENSOR WITH TRENCH CAPACITOR AND METHOD OF MANUFACTURING THE SAME

(71) Applicant: Powerchip Semiconductor Manufacturing Corporation, Hsinchu (TW)

(72) Inventors: Chia-Lin Chen, Hsinchu (TW); Chen-Ming Huang, Hsinchu (TW)

(73) Assignee: Powerchip Semiconductor Manufacturing Corporation, Hsinchu (TW)

(21) Appl. No.: 18/909,913

(22) Filed: Oct. 8, 2024

(30) Foreign Application Priority Data
Apr. 2, 2024 (TW) 113112462

(51) Int. Cl. H01L 27/146; H04N 25/59

(52) U.S. Cl. CPC H10F 39/811; H04N 25/59; H10D 1/68; H10F 39/18; H10F 39/80373; H10F 39/8053; H10F 39/8063

(57) ABSTRACT

A CMOS image sensor is provided in the present invention, including a transfer gate on the frontside of substrate, a photodiode in the substrate at one side of the transfer gate, a floating diffusion region in the substrate close to the frontside at another side of the transfer gate, a trench capacitor in a capacitor trench extending from the backside into the substrate, and a TSV penetrating the substrate, wherein the floating diffusion region is connected with the TSV through a frontside interconnect, and the trench capacitor is connected with the TSV through a backside interconnect.

### BACKGROUND OF THE INVENTION

### 1. Field of the Invention

The present invention relates generally to a complementary metal-oxide-semiconductor image sensor (CMOS image sensor) and method of manufacturing the same, and more specifically, to a CMOS image sensor with trench capacitor and method of manufacturing the same.

### 2. Description of the Prior Art

Electronic equipment having semiconductor devices are essential for many modern applications. Solid-state (e.g. semiconductor) image sensors are commonly involved in electronic equipment with functions like light sensing and photograph for the purpose of image acquisition, wherein CMOS image sensor are widely used in various applications and fields, such as digital camera and mobile phone cameras. In comparison to conventional charge-coupled device (CCD) image sensor, CMOS image sensor is provided with advantages like less power consumption, lower driving voltages and faster speed. CMOS image sensor typically includes an array of picture elements (e.g. pixels). Each pixel includes transistors, capacitors and photodiodes, wherein electrical energy is induced in the photodiode upon exposure to the luminous environment. Each pixel generates electrons proportional to an amount of light entering the pixel. The electrons are converted into a voltage signal in the pixels and are further transformed into digital signal.

In actual applications, sometimes large brightness changes and differences may occur in photography or photosensitive scenes. The difference in light quantity under different lighting environments will have a negative impact on the sensing of CMOS image sensor. This is because current highly-miniaturized CMOS image sensor is operated by converting received image light into an electron carrier through photodiode and then storing it in a floating diffusion region with fixed conduction band energy level and smaller energy capacity. A transfer transistor is used to control the read/transfer of these electrons to the floating diffusion region, and the accumulated electrons in the floating diffusion region are then read to obtain an image signal. When the light is strong or the exposure time is too long, the converted electrons may easily exceed inherent well capacity of the floating diffusion region and overflow from the floating diffusion region to surrounding pixels, causing the read image to have a blooming phenomenon. The bright details of the image are therefore distorted. On the contrary, when the light is weak, fewer electrons may induce insufficient output signal voltage, causing the read image dark or have insufficient contrast. Therefore, conventional CMOS image sensors cannot acquire realistic and satisfactory images in a scene with excessive contrast between light and dark.

In order to solve the problem above, one of the solutions commonly known in the industry today is dual conversion gain (DCG) circuit design, featuring an external capacitor with larger capacity connected next to the original floating diffusion region, and an additional gate is set to control the switching of the conversion gain during sensing, so that two different sensing modes of low conversion gain and high conversion gain can be performed for high-illumination and low-illumination pixels respectively, achieving a high dynamic range (HDR) image capture that balance light and dark scenes.

However, since the aforementioned dual conversion gain solution requires the addition of additional transistors and capacitors, the space of original components will be compressed under limited layout area, especially the space of photodiodes, which will reduce full-well capacity (FWC) of the component, impacting the signal-to-noise ratio (S/N) and dynamic range performance of the sensor. Therefore, those skilled in the art must improve existing designs of CMOS image sensor, in order to solve the problems above.

### SUMMARY OF THE INVENTION

In the light of the aforementioned issues encountered in conventional skill, the present invention hereby provides a novel design of CMOS image sensor, with feature of setting the additional capacitor required by dual conversion gain on the backside of substrate in the form of trench, so that high dynamic range image capture may be achieved without compromising the layout area on the frontside of the substrate.

One aspect of the present invention is to provide a CMOS image sensor with trench capacitor, including: a substrate with a frontside and a backside; a transfer gate on the frontside; a photodiode in the substrate at one side of the transfer gate; a floating diffusion region in the substrate close to the frontside at another side of the transfer gate; a trench capacitor in a capacitor trench extending from the backside into the substrate, and a bottom of the capacitor trench is spaced from the frontside by a predetermined distance; and a TSV penetrating the substrate with two ends exposed from the frontside and the backside respectively, wherein the floating diffusion region is connected with the TSV through a frontside interconnect on the frontside, and the trench capacitor is connected with the TSV through a backside interconnect on the backside.

Another aspect of the present invention is to provide a method of manufacturing a CMOS image sensor with trench capacitor, including: providing a substrate with a frontside and a backside; forming a photodiode and a floating diffusion region in the substrate; forming a transfer gate and a frontside interconnect on the frontside, the transfer gate is between the photodiode and the floating diffusion region, and the frontside interconnect is connected with the floating diffusion region; forming a capacitor trench extending into the substrate on the backside, and a bottom of the capacitor trench is spaced from the frontside by a predetermined distance; forming a trench capacitor in the capacitor trench; forming a TSV in the substrate, one end of the TSV is exposed from the frontside and connected with the floating diffusion region through the frontside interconnect, and another end of the TSV is exposed from the backside;

and forming a backside interconnect on the backside, and the backside interconnect is connected with the another end of the TSV and the trench capacitor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

This specification contains accompanying drawings, which constitute a part of this specification, so that readers can have a further understanding of the embodiments of present invention. The drawings depict embodiments of the present invention and, together with their corresponding descriptions, explain the principles thereof. In these illustrations:

FIG. 1 is a circuit diagram of a CMOS image sensor with dual conversion gain in accordance with one embodiment of the present invention;

FIGS. 2-7 are cross-sections illustrating a process flow of manufacturing a CMOS image sensor with trench capacitor in accordance with one embodiment of the present invention; and

FIGS. 8-12 are cross-sections illustrating a process flow of manufacturing a CMOS image sensor with trench capacitor in accordance with another embodiment of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

In addition, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon (Si), germanium (Ge), gallium arsenide (GaAs), indium phosphide (InP), etc.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

As used herein in the description of the invention, the “N” and “P” designations, as in “N type” and “P type”, are used in the common manner to designate donor and acceptor type impurities which promote electron and hole type carriers respectively as the majority carriers. The “++” symbol, when used as a suffix with an impurity type should be interpreted to mean that the doping concentration of that impurity is heavier than the doping associated with just the letter identifying the impurity type without the “+” suffix. Conversely, the “−” symbol, when used as a suffix with an impurity type should be interpreted that the doping concentration of that impurity is lighter than the doping associated with just the letter identifying the impurity type without the “−” suffix.

The term “pixel” refers to a picture element unit cell containing a photo sensor and devices, such as transistors for converting electromagnetic radiation into an electrical signal. An image device would include multiple pixels arranged in a 2D array with multiple columns and rows, and peripheral circuit and other components may be provided around the pixel array, which may include various circuits for the operation and process of the image sensor. For purposes of illustration, a representative pixel is illustrated in the figures and description herein, and typically fabrication of all pixels in an imager will proceed simultaneously in a similar fashion. It should be understood that the invention is applicable to pixel cells in any arrangement and orientation for integration with other components of a semiconductor device.

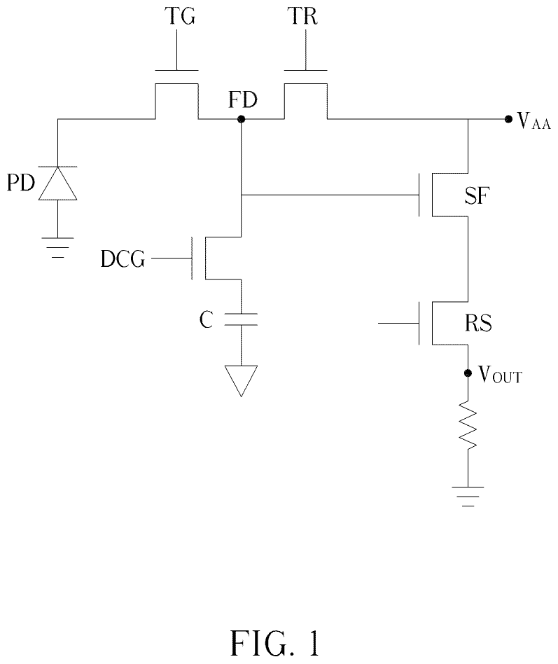

A circuit design of CMOS image sensor with dual conversion gain of the present invention will now be described in following embodiment with reference to FIG. 1. Please note that, although the drawings provided in the specification all illustrate only single pixel unit, it should be understood that the actual CMOS image sensor may include multiple pixels arranged in a 2D array with surrounding peripheral circuits, which may including various circuits required by the operation and process of the image sensor.

Please refer first to FIG. 1, which is a circuit diagram of a CMOS image sensor with dual conversion gain. It should be noted that in this figure, a CMOS image sensor is a pixel unit. Each pixel unit has repeated, similar components and will receive incident light from its corresponding area. As shown in FIG. 1, the CMOS image sensor of present invention includes components like a photodiode PD, a transfer gate TG, a reset transistor TR, a gate for dual conversion gain DCG, a source follower SF, a column selection transistor RS and a capacitor C. Among these components, one terminal of the photodiode PD is grounded, and another terminal is coupled to a floating diffusion region FD (or referred as a floating diffusion node) through the transfer gate TG. The photodiode PD can convert the received image light into electron carriers through photoelectric effect and accumulate them. The floating diffusion area FD itself acts as a capacitor. When the transfer gate TG is turned on, the accumulated electrons generated at the photodiode PD can be transferred to the floating diffusion area FD for storage. The existence of floating diffusion area FD can achieve functions of correlated double sampling (CDS) and noise reduction. One terminal of the reset transistor TR is connected to the floating diffusion region FD, the gate of source follower transistor SF is also connected to the floating diffusion region FD, and another terminal of the reset transistor TR and the source follower transistor SF are coupled to a tunable high potential VAA. When the reset transistor TR is turned on, the electrons stored in the floating diffusion region FD may be cleared to reset its potential. The voltage signal of source follower transistor SF depends on the potential of floating diffusion region FD. The existence of source follower transistor SF can amplify the image signal stored in the floating diffusion region FD for signal output. The source follower transistor SF is connected in series with the column selection transistor RS. The column selection transistor RS can connect the image output signal V_{OUT} generated by the pixels to the read circuit in sequence, so that the signals generated by multiple pixels can constitute an image.

Furthermore, refer still to FIG. 1. In the embodiment of present invention, one terminal of the floating diffusion region FD is also coupled to a gate for double conversion gain DCG and a capacitor C. The gate for double conversion gain DCG and the capacitor C are essential elements to realize high dynamic range (HDR) image capture in the scheme of double conversion gain. In response to bright scenes, the gate for double conversion gain DCG of the CMOS image sensor will be opened, so that the floating diffusion area FD and the capacitor C at two sides of the gate for double conversion gain DCG can be connected in series to form a larger capacitor collectively, thereby increasing full-well capacity (FWC) of the sensor and therefore preventing excess electrons from overflowing to distort the bright details in the image. This is the low conversion gain (LCG) operation mode in the dual conversion gain scheme. On the other hand, in response to darker scenes that require high conversion gain (HCG), the gate for double conversion gain DCG of the CMOS image sensor will be turned off, so that the sensor can only uses original floating diffusion area FD as an electron trap to store image signals, and a higher signal-to-noise ratio (S/N) and higher sensitivity can be achieved in low-light environments, avoiding insufficient contrast in dark tone images. This is the high conversion gain operation mode in the dual conversion gain scheme.

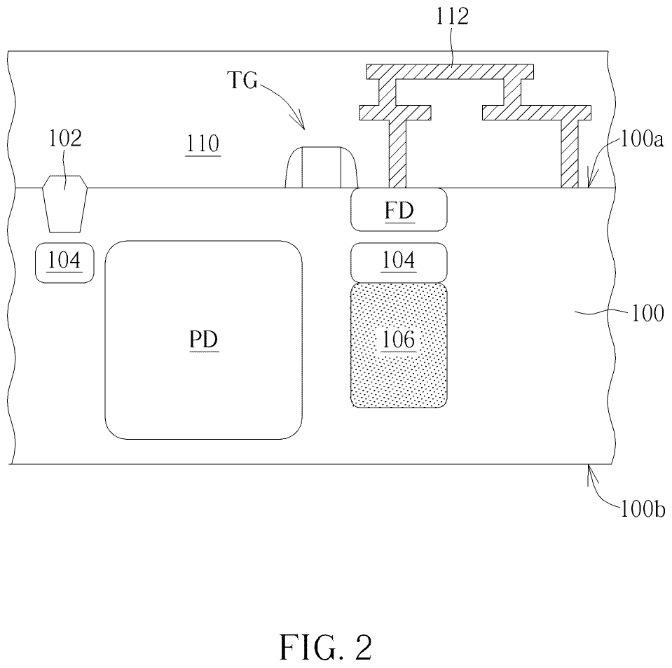

After introducing the circuit of CMOS image sensor with dual conversion gain function, a process follow of manufacturing a CMOS image sensor with trench capacitor in an embodiment of the present invention will be described hereinafter with reference to the cross-sections of FIGS. 2-7. It should be noted that since the focus of present invention lies in the components related to the double conversion gain in the photodiode area of CMOS image sensor and their relative positions and connection relationships, the cross-sections in these figures only show relevant components and ranges in the circuit configuration of FIG. 1. Other components, including reset transistor TR, source follower transistor SF, and column selection transistor RS, etc., will not be shown in these cross-sections.

Please refer first to FIG. 2. At the beginning of the step, a semiconductor substrate 100 is provided as a device base, such as a P-type doped silicon substrate. The semiconductor substrate 100 has a frontside 100a and a backside 100b, wherein the frontside 100a (upward in the figure) is the side where semiconductor devices (e.g. various transistors) in the CMOS image sensor are predetermined to be formed. The backside 100b (downward in the figure) is the side where the trench capacitor of CMOS image sensor is predetermined to be formed. The present invention is preferably a design of back side illuminated (BSI) CMOS image sensor, meaning the image light is designed to be incident from the backside 100b of semiconductor substrate 100, so relevant components in the CMOS image sensor, such as color filter and microlens, will be disposed on the backside 100b. The advantage of BSI image sensor is that the incident image light will not be blocked by the dielectric layer and interconnects on the substrate and may directly hit the photodiode, which allows the image sensor to have higher photosensitivity.

Refer still to FIG. 2. After the semiconductor substrate 100 is provided, an ion implantation process is performed to form different doped regions like photodiode PD, floating diffusion region FD, implanting isolation region 104 and the electrode doped region 106 in the semiconductor substrate 100. The aforementioned ion implantation process can define different ranges and depths of the doped regions through patterned photoresist and different implantation energies, and the doped dopants may be activated through the tempering process to form required profiles for the doped regions. Among them, the photodiode PD may be a N type photodiode, which is a semiconductor P-N junction or PIN junction. Image light entering the photodiode PD will be absorbed and generate a current, so that the signal of image light may be converted into an electrical signal in the form of optoelectrons for storage or processing. Device isolating structures 102 may be formed on the semiconductor substrate 100, such as shallow trench isolations (STIs), deep trench isolations (DTIs) or a local oxidation structure of silicon (LOCOS), to separate and define pixel units. The potential energy barrier of the device isolating structure 102 will be higher than the energy barrier of the photoelectric conversion region, so that carriers can accumulate a certain amount in the region and prevent the carriers from leaking to adjacent pixels.

Refer still to FIG. 2. The floating diffusion region FD is formed in the semiconductor substrate 100 adjacent to the photodiode PD and close to the frontside 100a to serve as one of the capacitors of the CMOS image sensor. In the embodiment of present invention, the floating diffusion region FD may be a N+ type doped region, meaning that its N type doping concentration is higher than the one of photodiode PD. In this way, when the transfer gate TG is turned on, the photoelectrons accumulating in the photodiode PD in the read operation will flow into the floating diffusion region FD and stored there due to lower well level of the floating diffusion region FD. In the embodiment of present invention, an implanting isolation region 104 and an electrode doped region 106 are further formed in the substrate below the floating diffusion region FD, which preferably overlap the floating diffusion region FD above in a direction perpendicular to the frontside 100a of substrate. In the embodiment, the electrode doped region 106 functions as a bottom electrode for a trench capacitor to be formed in later process, which may be a N+ type doped region like the floating diffusion region FD. The implanting isolation region 104 may be a P+ type doped region, which isolates the floating diffusion region FD and the electrode doped region 106 of the same doping type to prevent them from electrically connecting. The implanting isolation area 104 can also be formed in the substrate around the photodiode PD, such as below the device isolating structure 102, which has the effect of avoiding signal crosstalk between pixels.

Refer still to FIG. 2. After the doped regions like photodiode PD, the floating diffusion region FD, the implanting isolation region 104 and the electrode doped region 106 are formed, general CMOS front-end-of-line (FEOL) and back-end-of-line (BEOL) process are performed on the frontside 100a of semiconductor substrate 100 to form various transistors (only the transfer gate TG is shown in the figure) and interconnects 112 required by the CMOS image sensor. The transfer gate TG is formed on the frontside 100a between the photodiode PD and the floating diffusion region FD to serve as a gate between the two diffusion regions for determining whether the accumulated photoelectrons generated by the photodiode PD transfer to the floating diffusion area FD. The interconnects 112 are formed in the interlayer dielectric (ILD) layer 110, which may be composed of multiple vias/contacts and metal layers and be electrically connected with the floating diffusion region FD in the substrate. The interconnects 112 may be made of metal, e.g. aluminum (Al), tungsten (W) or copper (Cu). The ILD layer 110 may be composed of a pre-metal dielectric (PMD) layer and a multilayered inter-metal dielectric (IMD) layer with material like silicon oxide, phosphosilicate glass (PSG), borosilicate glass (BSG), Boron phosphorus silicon glass (BPSG) or tetraethoxysilane (TEOS), silicon nitride (SiN), silicon oxynitride (SiON) and low-k materials, etc.

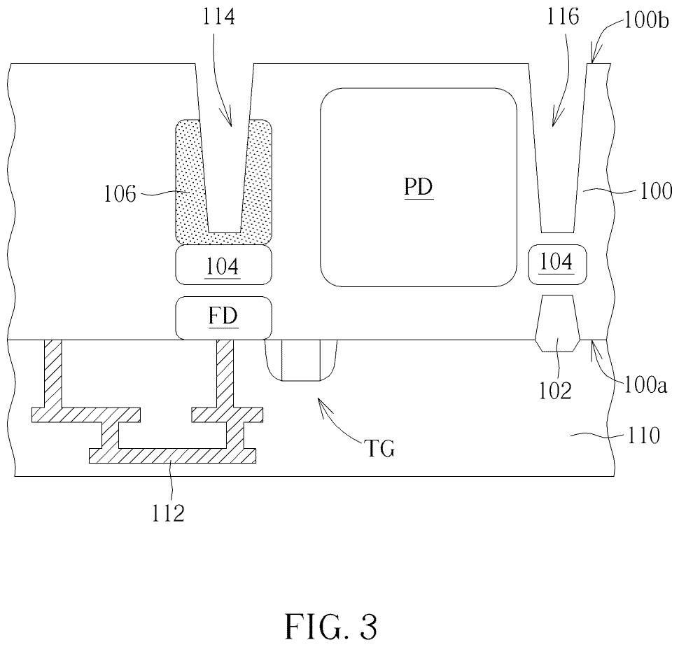

After completing the various doped regions in the substrate and the CMOS process on the frontside of substrate, the entire semiconductor substrate 100 is then flipped to perform backside process. It should be noted that the subsequent embodiments of FIGS. 3-7 will be presented with the backside of substrate oriented upwardly. The advantage of this backside process is that it may be compatible and integrated with conventional process for BSI CMOS image sensor.

Please refer to FIG. 3. After the semiconductor substrate 100 is flipped, a capacitor trench 114 and a deep trench 116 are formed on the backside 100b of the semiconductor substrate 100. In the embodiment of present invention, the capacitor trench 114 and the deep trench 116 may be integrated and formed in the same process, so that the method of present invention can be compatible and integrated into the currently available BSI CMOS image sensor process without additional step for forming trenches, which is one of its advantages. The capacitor trench 114 and the deep trench 116 can be formed through a photolithography process, which preferably uses an anisotropic dry etching process, such as deep reactive ion etching (DRIE), to ensure that the formed trenches have straight sidewalls. The capacitor trench 114 preferably overlaps the floating diffusion region FD, implanting isolation region 104 and the electrode doped region 106 in the substrate in a direction vertical to the backside 100b of substrate, with its bottom extending into the electrode doped region 106 to form trench capacitor later. On the other hand, the deep trenches 116 are preferably around the entire pixel unit, for example, overlapping the implanting isolation region 104 and the device isolating structure 102 in the direction vertical to the backside of substrate 100b, so that the subsequently formed deep trench isolations can isolate and define the pixel units of image sensor and function as a barrier wall to avoid the photons incident on the pixel and the generated electrons entering pixels therearound and causing color mixing or crosstalk issue.

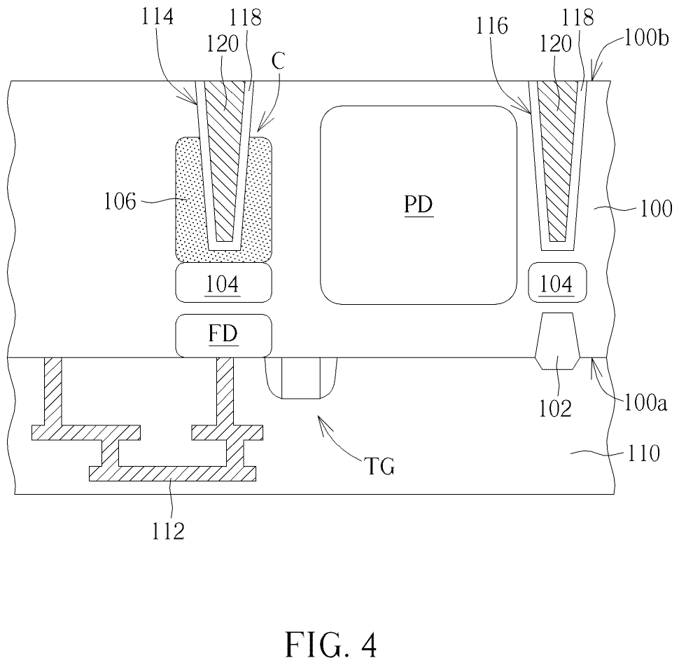

Please refer to FIG. 4. After the capacitor trench 114 and deep trench 116 are formed, a dielectric layer 118 and a conductive layer 120 are formed sequentially in the capacitor trench 114 and the deep trench 116. The dielectric layer 118 will be between the conductive layer 120 and the electrode doped regions 106. The dielectric layer 118 may be made of oxide, nitride or high-k material, e.g. hafnium oxide (HfO₂), aluminum oxide (Al₂O₃) or tantalum oxide (Ta₂O₅). The material of conductive layer 120 can be titanium nitride (TiN) or doped polysilicon, which can fill the remaining trench space through CVD or PVD process. The dielectric layer 118 and conductive layer 120 on the backside 100b of the semiconductor substrate 100 may be removed through CMP process after deposition. In the embodiment of present invention, the dielectric layer 118 and conductive layer 120 are integrated and formed in the same process, so that the method of present invention may be compatible with currently available BSI CMOS image sensor process without additional steps for forming other layer structures, which is one of its advantages. In the embodiment of present invention, the dielectric layer 118 and the conductive layer 120 in the capacitor trench 114 serve as a capacitive dielectric layer and a top electrode respectively, which constitute a trench capacitor C of the present invention together with the electrode doped region 106 in the substrate. The dielectric layer 118 and conductive layer 120 in the deep trench 116 together form collectively a deep trench isolation DTI, which can define pixel units of the CMOS image sensor and function as a barrier wall to avoid the photons incident on the pixel and the generated electrons entering pixels therearound and causing color mixing or crosstalk issue, and the optical path of incident photons in the pixel may be increased to greatly improve the quantum efficiency of the photodiode.

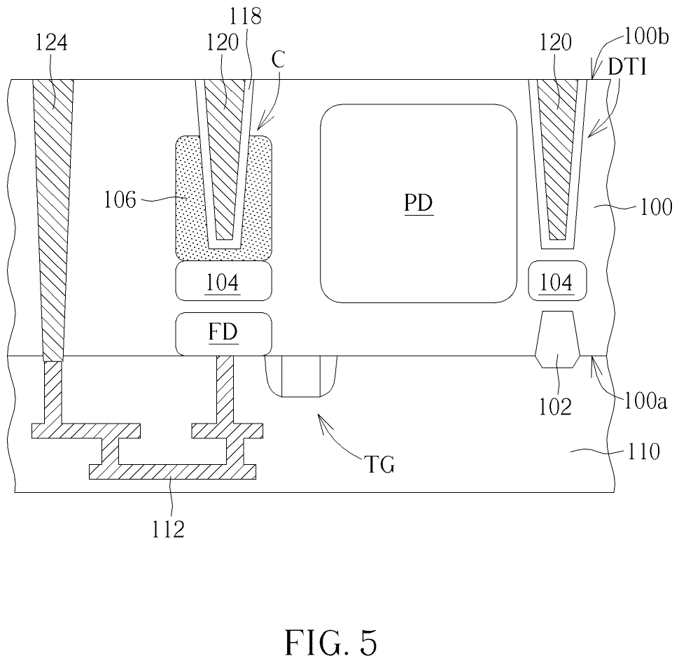

Please refer to FIG. 5. After the trench capacitor C and the deep trench isolation DTI are formed, a through silicon via (TSV) 124 is formed in the semiconductor substrate 100. Similar to the formation of trench capacitor C, the TSV 124 may be formed by forming a TSV hole through entire semiconductor substrate 100 through a photolithography process and then filling the TSV hole with a dielectric layer (e.g. silicon oxide), a diffusion barrier layer (e.g. titanium nitride or tantalum nitride) and conductive materials (e.g. copper or tungsten). Two ends of the TSV 124 are exposed respectively from the frontside 100a and backside 100b of the semiconductor substrate 100, which is connected to the previously formed interconnect 112 on the front side 100a. In the embodiment of present invention, the TSV 124 serves as a channel for connecting the floating diffusion region FD on the frontside of substrate and the trench capacitor C on the backside.

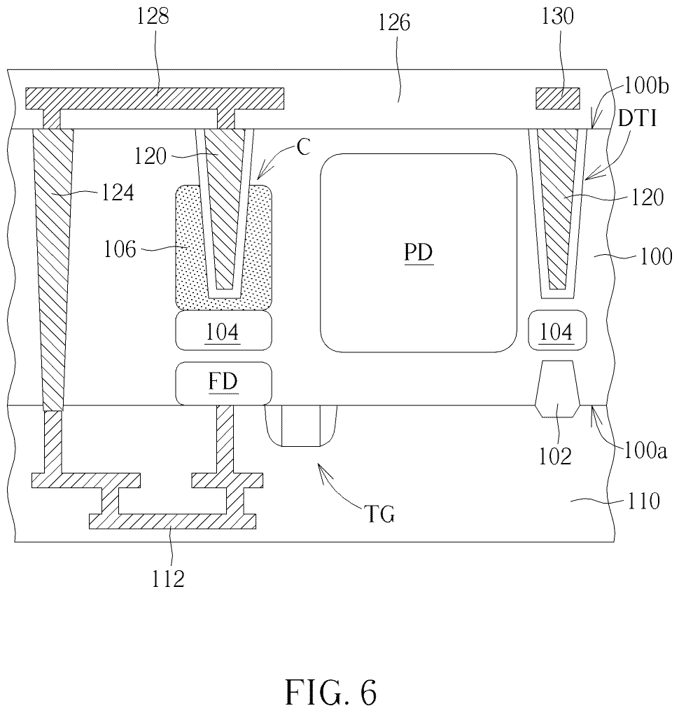

Please refer to FIG. 6. After the TSV 124 is formed, a backside interconnect 128 (relative to the frontside interconnects 112) is formed on the backside 100b of semiconductor substrate 100. In the embodiment of present invention, the backside interconnect 128 is used to connect the top electrode 120 of trench capacitor C and the TSV 124, so that the top electrode 120 of trench capacitor C can be connected with the floating diffusion region FD at the frontside through the TSV 124. The bottom electrode of trench capacitor C (i.e. the electrode doped region 106) is also connected with the backside interconnect 128 (not shown). The backside interconnect 128 is formed in a dielectric layer 126, which may be composed of multiple vias and multiple metal layers. It should be noted that in the embodiment of present invention, the backside interconnect 128 and the metal grid 130 of CMOS image sensor can be integrated and formed in the same process, so that the method of present invention may be compatible to currently available process of BSI CMOS image sensor without additional steps for forming interconnects, which is one of its advantages. The metal grid 130 may be formed on the backside 100b around the photodiode area, and may overlap the previously formed deep trench isolation DTI and the implanting isolation region 104 in a direction vertical to the backside of substrate. The material of metal grid 130 and the backside interconnects 128 may be metal, such as tungsten (W). The metal grid 130 can reflect the light entering the corresponding pixels to increase sensitivity and at the same time reducing crosstalk between pixels.

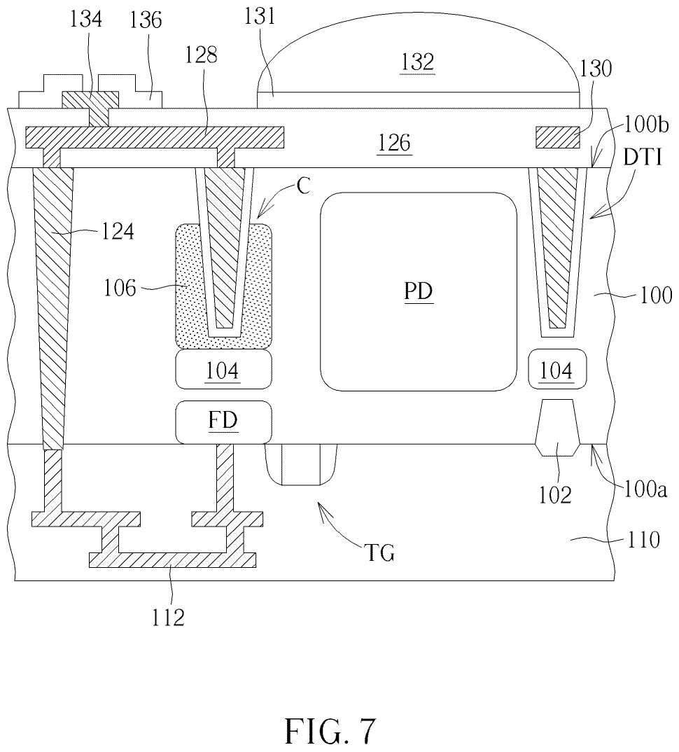

Please refer to FIG. 7. After the backside interconnects 128 and the metal grid 130 are formed, structures like color filter 131, microlens 132 and metal pads 134 are then formed on the dielectric layer 126 at the backside. The color filter 131 and microlens 132 overlap the photodiode PD in the substrate in a direction vertical to the backside 100b. For each pixel, the color of color filter 131 may be different. For example, a Bayer array composed of three different colors such as red (R), green (G), and blue (B) may be formed by spin-coating photosensitive resins containing pigments, such as pigments or dyes, on the substrate. Each microlens 132 corresponds to a pixel unit, which may be formed of resin-based materials, e.g. styrene, acrylic or siloxane. The microlens 132 can focus the incident light on the corresponding pixel and enter its photodiode PD. The pads 134 are used to connect the CMOS image sensor to external circuits, which are connected to the backside interconnects 128 and even the frontside interconnects 112. There is also a passivation layer 136 covering and exposing a portion of the pad 134. In this way, the production of the CMOS image sensor with trench capacitor of the present invention is completed.

As can be understood from the embodiments above, the advantage of CMOS image sensor of the present invention lies in the addition of a trench capacitor to achieve HDR image capture that balances light and dark scenes, and the trench capacitor is designedly set on the backside of substrate without occupying the photodiode layout area on the frontside. At the same time, the process of these components can all be integrated with currently available BSI CMOS image sensor process without additional steps, which is an advantage of the present invention.

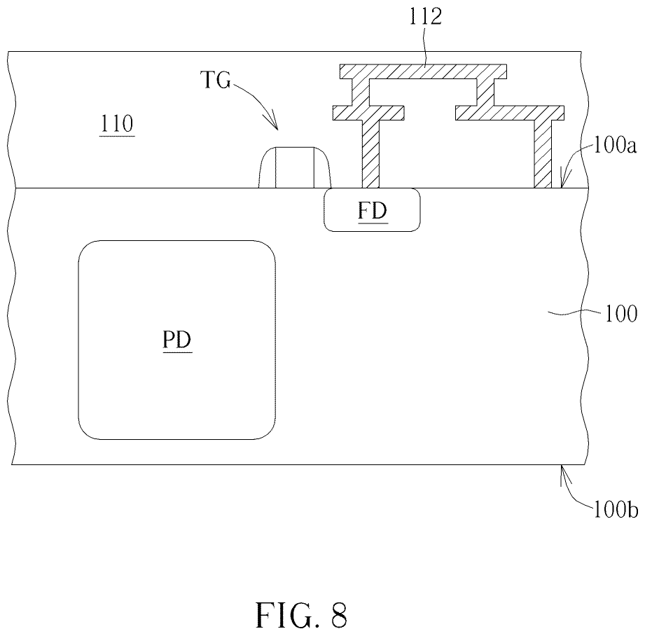

Next, the process of manufacturing a CMOS image sensor with trench capacitor in accordance with another embodiment of the present invention will be described with reference to the schematic cross-sections diagrams in FIG. 8 to FIG. 12 in sequence. This process is suitable for the design of BSI CMOS image sensor without deep trench isolation (DTI).

First, please refer to FIG. 8. FIG. 8 is similar to FIG. 2. Doped regions like photodiode PD and floating diffusion region FD are formed in the semiconductor substrate 100 and various transistors like transfer gate TG, an ILD layer 110 and frontside interconnects 112 are formed on the frontside 100a. The difference of embodiment in FIG. 8 is that there are no implanting isolation region and electrode doped region functioning as the lower electrode formed in the substrate.

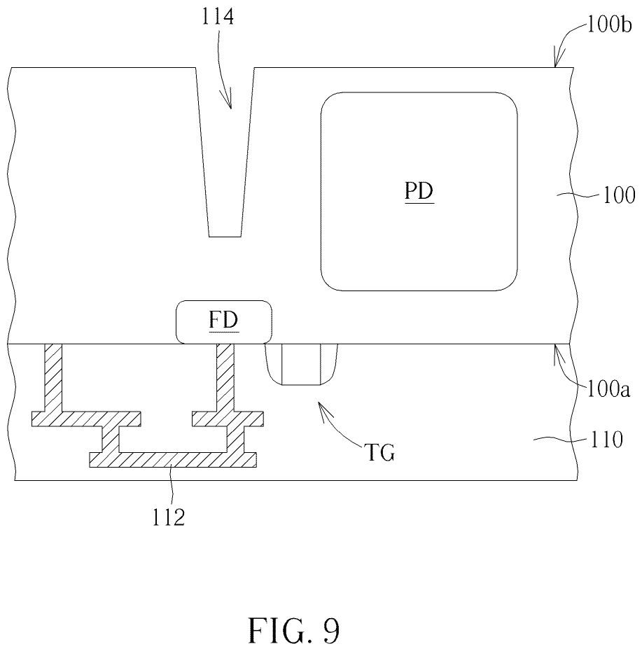

Please refer to FIG. 9. After forming various doped regions in the substrate and the transistors and interconnects 112 on the frontside, similar to FIG. 3, the semiconductor substrate 100 is then flipped and a capacitor trench 114 is formed on the backside 100b. It should be noted that this embodiment does not form deep trenches 116 at the same time, so it is suitable for BSI CMOS image sensor scheme that do not have any deep trench isolations. Since no deep trench isolation is provided, the advantage of this embodiment is that the layout area of photodiode can be increased to improve its full well capacity.

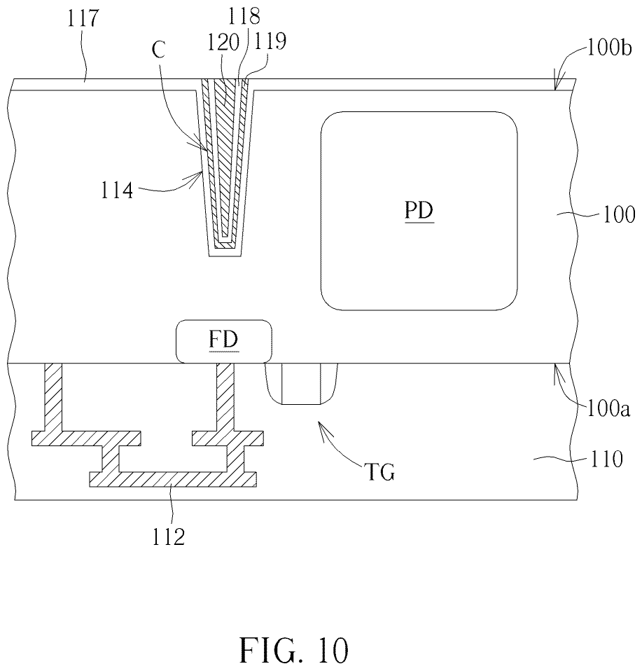

Please refer to FIG. 10. After the capacitor trench 114 is formed, layer structures like insulating layer 117, lower electrode 119, capacitive dielectric layer 118 and top electrode 120 are formed sequentially in the capacitor trench 114, thus forming a trench capacitor C. In the embodiment, the insulating layer 117, lower electrode 119 and capacitive dielectric layer 118 are sequentially and conformally formed on the surface of capacitor trench 114, while the remaining trench space is filled by the top electrode 120. The insulating layer 117 may be further covered on the backside 100b of semiconductor substrate 100, wherein the material of insulating layer 117 may be silicon oxide, the material of capacitive dielectric layer 118 may be oxide, nitride or high-k material, e.g. hafnium oxide (HfO₂), aluminum oxide (Al₂O₃), tantalum oxide (Ta₂O₅), and the material of top electrode 120 and bottom electrode 119 may be titanium nitride or doped polysilicon. These layer structures can be formed through deposition processes like CVD, PVD or ALD. The difference between this embodiment and previous embodiment is that the bottom electrode 119 of trench capacitor C in this embodiment is in the form of a conductive layer rather than a doped region. Therefore, the process is not easily affected by the thermal budget of wafer and the layout area of trench capacitor can be better controlled.

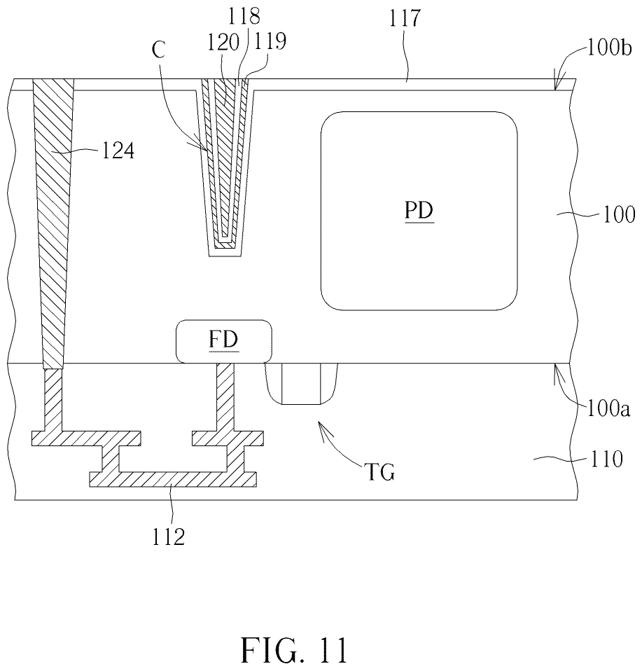

Please refer to FIG. 11. After the trench capacitor C is formed, similar to the steps of FIG. 5, TSV 124 is formed in the semiconductor substrate 100 as a channel to connect the floating diffusion region FD on the frontside and the trench capacitor C on the backside of substrate. One end of the TSV 124 is connected with the frontside interconnect 112 on the frontside 100a, while the other end is exposed from the insulating layer 117 on the backside 100b.

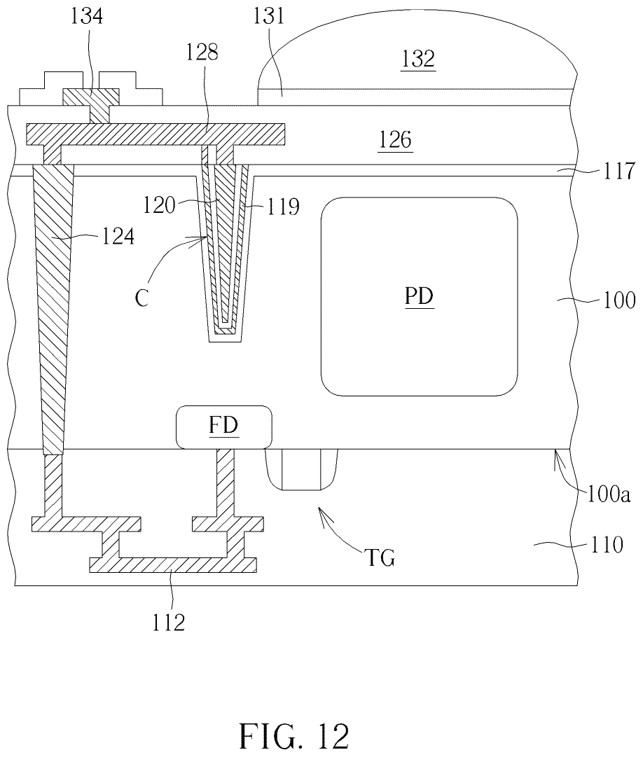

Please refer to FIG. 12. After the TSV 124 is formed, similar to the steps of FIG. 6 and FIG. 7, a backside interconnect 128, a color filter 131, a microlens 132 and a metal pad 134 are formed on the insulating layer 117. In the embodiment of present invention, the backside interconnect 128 connects the top electrode 120 of trench capacitor C and the TSV 124, so that the top electrode 120 of trench capacitor C may be connected with the floating diffusion region FD on the frontside through the TSV 124, and the bottom electrode 119 of trench capacitor C is also connected with the backside interconnect 128. Likewise, the back interconnect 128 of this embodiment can also be integrated and formed with the metal grid of CMOS image sensor in the same process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A CMOS image sensor with trench capacitor, comprising:
a substrate with a frontside and a backside;
a transfer gate on said frontside;
a photodiode in said substrate at one side of said transfer gate;
a floating diffusion region in said substrate close to said frontside at another side of said transfer gate;
a trench capacitor in a capacitor trench extending from said backside into said substrate, and a bottom of said capacitor trench is spaced from said frontside by a predetermined distance; and
a TSV penetrating said substrate with two ends exposed from said frontside and said backside respectively, wherein said floating diffusion region is connected with said TSV through a frontside interconnect on said frontside, and said trench capacitor is connected with said TSV through a backside interconnect on said backside.

2. The CMOS image sensor with trench capacitor of claim 1, wherein said trench capacitor overlaps said floating diffusion region in a direction vertical to said backside.

3. The CMOS image sensor with trench capacitor of claim 1, wherein said trench capacitor further comprises a top electrode, a bottom electrode and a capacitive dielectric layer between said top electrode and said bottom electrode, said bottom electrode is a doped region surrounding said capacitor trench in said substrate, said capacitive dielectric layer is formed on a surface of said capacitor trench, and said top electrode is a conductive layer formed on said capacitive dielectric layer.

4. The CMOS image sensor with trench capacitor of claim 3, further comprising a deep trench isolation around said photodiode, said deep trench isolation is provided with a dielectric layer and a conductive layer formed in a deep trench extending from said backside into said substrate, wherein said deep trench and said capacitor trench are formed integrally in the same process, and said dielectric layer and said conductive layer of said deep trench isolation are formed integrally with said capacitive dielectric layer and said top electrode of said trench capacitor in the same process.

5. The CMOS image sensor with trench capacitor of claim 3, further comprising an implanting isolation region in said substrate between said doped region and said floating diffusion region.

6. The CMOS image sensor with trench capacitor of claim 1, wherein said trench capacitor further comprises a bottom electrode, a capacitive dielectric layer and a top electrode formed sequentially on a surface of said capacitor trench, and said top electrode and said bottom electrode are conductive layer.

7. The CMOS image sensor with trench capacitor of claim 6, further comprising an insulating layer between said bottom electrode and said capacitor trench.

8. The CMOS image sensor with trench capacitor of claim 1, further comprising a metal grid on said backside around said photodiode, wherein said backside interconnect and said metal grid are formed integrally in the same process.

9. The CMOS image sensor with trench capacitor of claim 1, further comprising a color filter and a microlens on said backside, and said color filter and said microlens overlap said photodiode in a direction vertical to said backside.

10. A method of manufacturing a CMOS image sensor with trench capacitor, comprising:
providing a substrate with a frontside and a backside;
forming a photodiode and a floating diffusion region in said substrate;
forming a transfer gate and a frontside interconnect on said frontside, said transfer gate is between said photodiode and said floating diffusion region, and said frontside interconnect is connected with said floating diffusion region;
forming a capacitor trench extending from said backside into said substrate, and a bottom of said capacitor trench is spaced from said frontside by a predetermined distance;
forming a trench capacitor in said capacitor trench;
forming a TSV in said substrate, one end of said TSV is exposed from said frontside and connected with said floating diffusion region through said frontside interconnect, and another end of said TSV is exposed from said backside; and
forming a backside interconnect on said backside, and said backside interconnect is connected with said another end of said TSV and said trench capacitor.

11. The method of manufacturing a CMOS image sensor with trench capacitor of claim 10, wherein said trench capacitor overlaps said floating diffusion region in a direction vertical to said substrate.

12. The method of manufacturing a CMOS image sensor with trench capacitor of claim 10, further comprising forming a doped region surrounding said capacitor trench in said substrate as a bottom electrode for said trench capacitor.

13. The method of manufacturing a CMOS image sensor with trench capacitor of claim 12, further comprising forming an implanting isolation region in said substrate, and said implanting isolation region is in said substrate between said doped region and said floating diffusion region.

14. The method of manufacturing a CMOS image sensor with trench capacitor of claim 12, wherein said step of forming said capacitor trench on said backside further comprising simultaneously forming a deep trench on said backside.

15. The method of manufacturing a CMOS image sensor with trench capacitor of claim 14, wherein said step of forming said trench capacitor comprises forming a capacitive dielectric layer and a top electrode on said capacitor trench in order, and both of said capacitive dielectric layer and said top electrode are formed in said deep trench to constitute a deep trench isolation.

16. The method of manufacturing a CMOS image sensor with trench capacitor of claim 10, wherein said step of forming said trench capacitor comprises forming an insulating layer, a bottom electrode, a capacitive dielectric layer and a top electrode sequentially on said capacitor trench.

17. The method of manufacturing a CMOS image sensor with trench capacitor of claim 10, wherein said step of forming said backside interconnect on said backside further comprises simultaneously forming a metal grid on said backside around said photodiode.

18. The method of manufacturing a CMOS image sensor with trench capacitor of claim 10, further comprises forming a color filter and a microlens on said backside, and said color filter and said microlens overlap said photodiode in a direction vertical to said backside.
